(19) United States
(12) Patent Application Publication
(10) Pub. No.: US 2024/0355990 A1
(43) Pub. Date: Oct. 24, 2024

(54) DISPLAY PANEL, DISPLAY DEVICE, AND METHOD FOR MANUFACTURING DISPLAY PANEL

(71) Applicant: Tianma Advanced Display Technology Institute (Xiamen) Co., Ltd., Xiamen (CN)

(72) Inventors: Wei HE, Xiamen (CN); Zhibo YANG, Xiamen (CN); Yangui FENG, Xiamen (CN); Bingjun CAO, Xiamen (CN); Ning ZHANG, Xiamen (CN); Ming YANG, Xiamen (CN)

(73) Assignee: Tianma Advanced Display Technology Institute (Xiamen) Co., Ltd., Xiamen (CN)

(21) Appl. No.: 18/762,576

(22) Filed: Jul. 2, 2024

(30) Foreign Application Priority Data
Dec. 29, 2023 (CN) 202311872337.7

(51) Int. Cl. H01L 33/62; H01L 25/075

(52) U.S. Cl. CPC H01L 33/62; H01L 25/0753

(57) ABSTRACT

Provided are a display panel, a display device, and a method for manufacturing a display panel. The display panel includes a base substrate and a first signal line. The base substrate includes a first surface and a second surface. The degree of inclination of the first surface relative to the plane in which the display panel is located is greater than the degree of inclination of the second surface relative to the plane in which the display panel is located. At least part of the first signal line is in contact and connected with the first surface. At least part of the first signal line is in contact and connected with the second surface. The equivalent roughness of the second surface is less than the equivalent roughness of the first surface.

### CROSS-REFERENCE TO RELATED APPLICATION(S)

This application claims priority to Chinese Patent Application No. 202311872337.7 filed Dec. 29, 2023, the disclosure of which is incorporated herein by reference in its entirety.

### TECHNICAL FIELD

The present application relates to the field of display technology, in particular, a display panel, a display device, and a method for manufacturing a display panel.

### BACKGROUND

When a display device adopts the form of spliced display panels, gaps are formed between the display panels. To increase the proportion of a display region, the display panel adopts a narrow frame or frameless design. Some of the wires of the display panel are disposed on an array layer, and other wires are disposed on one side of a base substrate away from the array layer. Therefore, part of the signal lines (e.g. side wires) are configured at the one side of the base substrate, so that circuits at both sides of the base substrate are electrically connected through the signal lines. An edge exists at the connection between the front surface and side surface of the base substrate, making it easy for the side wires to detach or split from the front surface or side surface at the edge. Moreover, the connection strength between the side wires and the base substrate is affected, and the service life of the display panel is thus affected.

### SUMMARY

Embodiments of the present application provide a display panel, a display device, and a method for manufacturing a display panel, which can improve the firmness of the connection between a first signal line and a base substrate.

In a first aspect, an embodiment of the present application provides a display panel. The display panel includes a base substrate and a first signal line. The base substrate includes a first surface and a second surface. The degree of inclination of the first surface relative to the plane in which the display panel is located is greater than the degree of inclination of the second surface relative to the plane in which the display panel is located. At least part of the first signal line is in contact and connected with the first surface. At least part of the first signal line is in contact and connected with the second surface. The equivalent roughness of the second surface is less than the equivalent roughness of the first surface.

In a second aspect, an embodiment of the present application provides a display device. The display device includes multiple display panels described in the embodiment of the first aspect of the present application. Multiple display panels are disposed in parallel. The first surfaces of two adjacent display panels are in contact and connected with each other.

In a third aspect, a method for manufacturing a display panel is provided. The method includes the steps below. A base substrate including a first surface and a second surface is provided. The degree of inclination of the first surface relative to the plane in which the display panel is located is greater than the degree of inclination of the second surface relative to the plane in which the display panel is located. The base substrate is roughened such that the equivalent roughness of the second surface is less than the equivalent roughness of the first surface. A first signal line is manufactured to enable part of the first signal line to be in contact and connected with the second surface, and enable part of the first signal line to be in contact and connected with the first surface.

In the display panel, the display device, and the method for manufacturing a display panel provided by the embodiments of the present application, the substrate includes a first surface and a second surface that are not parallel, the first surface is more inclined relative to the plane in which the display panel is located, and the first surface is closer to the side end surface of the base substrate. The first surface and the second surface of the first signal line are in contact and connected to each other for transmitting signals. The equivalent roughness of the second surface is less than the equivalent roughness of the first surface, so the firmness of the connection between the first signal line and the first surface is greater than the firmness of the connection between the first signal line and the second surface. Thus, the risk of damage to the connection between the first surface and the first signal line caused by stress concentration can be effectively reduced, and the service life of the display panel described in embodiments of the present application can be extended.

### BRIEF DESCRIPTION OF DRAWINGS

To illustrate technical solutions in the embodiments of the present application more clearly, the drawings used in the embodiments of the present application are briefly described hereinafter. Apparently, the drawings described hereinafter illustrate part of embodiments of the present application, and those skilled in the art may obtain other drawings based on the drawings described hereinafter on the premise that no creative work is done.

FIG. 1 is a diagram illustrating the structure of a display panel according to an embodiment of the present application.

FIG. 2 is a diagram illustrating the structure of an edge of a base substrate and a first signal line of a display panel according to an embodiment of the present application.

FIG. 3 is a sectional view of the edge of the base substrate and the first signal line of the display panel taken along A-A according to an embodiment of the present application.

FIG. 4 is a side view of an edge of a base substrate of a display panel in a third direction according to an embodiment of the present application.

FIG. 5 is another side view of an edge of a base substrate of a display panel in a third direction according to an embodiment of the present application.

FIG. 6 is another side view of an edge of a base substrate of a display panel in a third direction according to an embodiment of the present application.

FIG. 7 is another side view of an edge of a base substrate of a display panel in a third direction according to an embodiment of the present application.

FIG. 8 is another side view of an edge of a base substrate of a display panel in a third direction according to an embodiment of the present application.

FIG. 9 is another side view of an edge of a base substrate of a display panel in a third direction according to an embodiment of the present application.

FIG. 10 is another side view of an edge of a base substrate of a display panel in a third direction according to an embodiment of the present application.

FIG. 11 is another side view of an edge of a base substrate of a display panel in a third direction according to an embodiment of the present application.

FIG. 12 is a side view of a first surface of the base substrate of the display panel in a second direction according to the embodiment of the present application in FIG. 11 or FIG. 10.

FIG. 13 is another side view of a first surface of the base substrate of the display panel in a second direction according to the embodiment of the present application in FIG. 11.

FIG. 14 is another side view of a first surface of the base substrate of the display panel in a second direction according to the embodiment of the present application in FIG. 11.

FIG. 15 is another side view of a first surface of the base substrate of the display panel in a second direction according to the embodiment of the present application in FIG. 8.

FIG. 16 is another side view of a first surface of the base substrate of the display panel in a second direction according to the embodiment of the present application in FIG. 8.

FIG. 17 is another side view of a first surface of the base substrate of the display panel in a second direction according to the embodiment of the present application in FIG. 8.

FIG. 18 is another side view of a first surface of the base substrate of the display panel in a second direction according to the embodiment of the present application in FIG. 8.

FIG. 19 is another side view of a first surface of the base substrate of the display panel in a second direction according to the embodiment of the present application in FIG. 8.

FIG. 20 is a diagram illustrating the structure of a display device according to an embodiment of the present application.

FIG. 21 is a sectional view of the display device taken along D-D according to the embodiment of the present application in FIG. 20.

FIG. 22 is a flowchart of a method for manufacturing a display panel according to an embodiment of the present application.

FIG. 23 is a flowchart of S2 of the method for manufacturing a display panel according to an embodiment of the present application.

FIG. 24 is a flowchart of S2 of the method for manufacturing a display panel according to an embodiment of the present application.

### REFERENCE LIST

1 base substrate
11 first surface
13 third surface
131 first sub-surface
132 second sub-surface
14 micro-structure part
141 first recess part
142 first protrusion part
15 side end surface
16 first reference surface
2 first signal line
21 first signal line segment
22 second signal line segment
3 array layer
4 light-emitting device layer
100 display device
101 display panel
X first direction
Y second direction
Z third direction
Q1 chamfer region
Q2 glass processing tolerance reserved region
Q3 signal line overlap region
Q4 protective film heat-affected region

### DETAILED DESCRIPTION

Features of various aspects and exemplary embodiments of the present application are described in detail below. In the following detailed description, numerous specific details are set forth to provide a thorough understanding of the present application. However, it is apparent to those skilled in the art that the present application may be implemented without some of these specific details. The description of the embodiments below is only to provide a better understanding of the present application by illustration of examples of the present application.

It is to be noted that if not in collision, the embodiments and features therein in the present application may be combined with each other. Embodiments are described below in detail in conjunction with the drawings.

Relationship terms such as first and second are used merely to distinguish one entity or operation from another entity or operation and do not necessarily require or imply any such actual relationship or order between these entities or operations. Additionally, the term “comprising”, “including”, or any other variant thereof is intended to encompass a non-exclusive inclusion so that a process, method, article, or device that includes a series of elements not only includes the expressly listed elements but also includes other elements that are not expressly listed or elements inherent to such a process, method, article, or device. In the absence of more restrictions, the elements defined by the statement “including a . . . ” do not exclude the presence of additional identical elements in the process, method, article, or device that includes the elements.

It should be understood that in describing the structure of a component, when one layer or region is referred to as being located “on” or “above” another layer or region, it may indicate that the one layer or region is directly on another layer or region or that other layers or regions are included between the one layer or region and another layer or region. Additionally, if the component is turned over, the one layer or region will be “below” or “under” the another layer or region.

Additionally, the term “and/or” in the present application only describes the association relationships of associated objects and indicates that three relationships may exist. For example, A and/or B may indicate three conditions of A alone, both A and B, and B alone. Additionally, the character “/” in the present application generally indicates that the front and rear associated objects are in an “or” relationship.

It should be understood that in the embodiments of the present application, “B corresponding to A” indicates that B is associated with A and that B may be determined according to A. However, it should also be understood that determining B according to A does not mean determining B only according to A and that B may also be determined according to A and/or other information.

The applicant finds that if a display device adopts the method of splicing display panels, the display panels usually adopt a narrow frame or frameless design. Therefore, some circuits are disposed at an array layer, and other circuits are disposed on one side of a base substrate away from the array layer. The two parts of circuits are electrically connected through side wires. Part of the side wires are located at a front side of the base substrate. Part of the side wires are located at a back side of the base substrate. Part of the side wires are located on a side end surface of the base substrate. The connection between the front surface and the side end surface of the base substrate is used as an example. A first signal line is bent at the connection between the front surface and the side end surface, and the shear stress generated by bending causes stress concentration at the connection between the front surface and the side end surface. The contact area between the side wires and the side end surface is relatively small so that situations such as splitting or detachment may occur between the side wires and the side end surface, thereby affecting the service life of the display panel.

In view of the preceding problems, the applicant proposes a display panel, a display device, and a method for manufacturing a display panel. The display panel includes a base substrate and a first signal line. The substrate includes a first surface and a second surface that are not parallel. The first surface is more inclined relative to the plane in which the display panel is located. The first surface is closer to the side end surface of the base substrate. It should be noted that herein, the display panel is macroscopically considered as a plane, and the plane is parallel to the display surface of the display panel. Hereinafter, the degree of inclination relative to the display panel may also be referred to as the degree of inclination relative to the plane in which the display panel is located. The first surface and the second surface of the first signal line are in contact and connected to each other for transmitting signals. The equivalent roughness of the second surface is less than the equivalent roughness of the first surface, so the firmness of the connection between the first signal line and the first surface is greater than the firmness of the connection between the first signal line and the second surface. Thus, the risk of damage to the connection between the first surface and the first signal line caused by stress concentration can be effectively reduced, and the service life of the display panel described in embodiments of the present application can be extended.

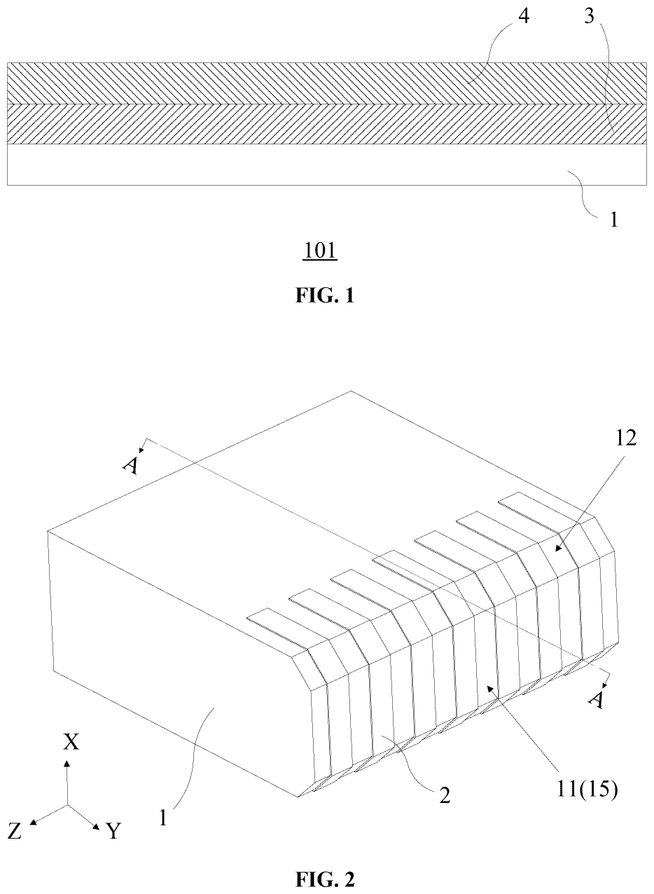

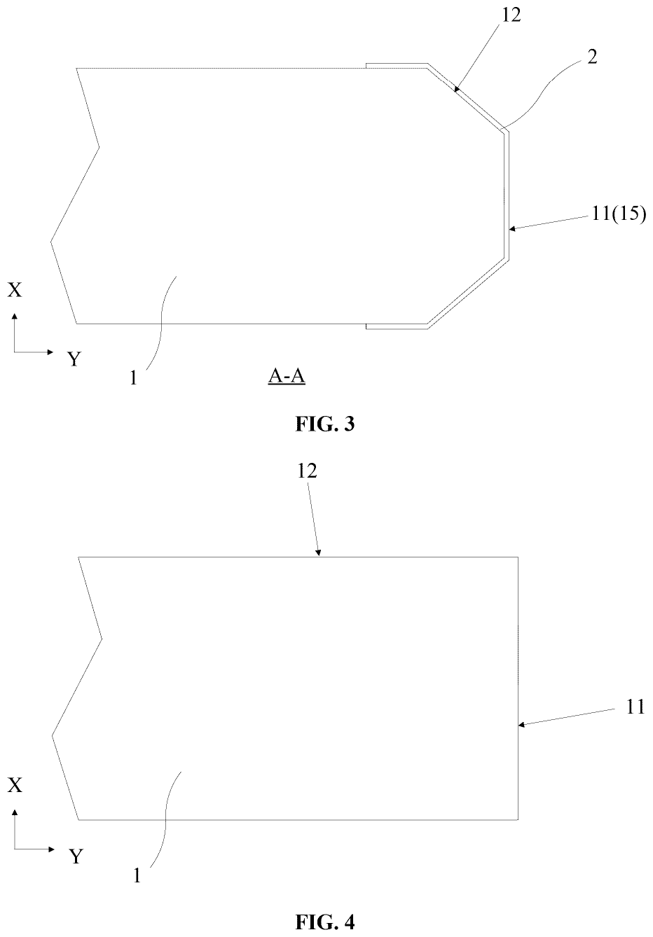

FIG. 1 is a diagram illustrating the structure of a display panel according to an embodiment of the present application. FIG. 2 is a diagram illustrating the structure of an edge of a base substrate and a first signal line of a display panel according to an embodiment of the present application. FIG. 3 is a diagram illustrating the structure of an edge of a base substrate and a first signal line of a display panel according to an embodiment of the present application.

With reference to FIG. 1 to FIG. 3, this embodiment of the present application provides a display panel 101, and the display panel 101 includes a base substrate 1 and a first signal line 2. The base substrate 1 includes a first surface 11 and a second surface 12, the degree of inclination of the first surface 11 relative to the plane in which the display panel 101 is located is greater than the degree of inclination of the second surface 12 relative to the plane in which the display panel is 101 located. At least part of the first signal line 2 is in contact and connected with the first surface 11, at least part of the first signal line 2 is in contact and connected with the second surface 12, and the equivalent roughness of the second surface 12 is less than the equivalent roughness of the first surface 11.

The base substrate 1 may be made of a polymer material such as glass, polyimide (PI), polycarbonate (PC), polyether sulfone (PES), polyethylene terephthalate (PET), polyethylene naphthalate (PEN), polyarylate (PAR), fiberglass reinforced plastic (FRP). The base substrate 1 may be transparent, translucent, or opaque. In the direction of the thickness of the display panel 101, the base substrate 1 includes a front surface and a back surface opposite to the first surface. The front surface faces a light-emitting device of the display panel 101, and an array layer of the display panel 101 is manufactured on the front surface. In a direction perpendicular to the direction of the thickness of the display panel 101, the base substrate 1 also includes a side end surface 15.

For ease of description, this embodiment of the present application includes a first direction X, a second direction Y, and a third direction Z that are perpendicular to each other. The first direction X is parallel to the direction of the thickness of the display panel 101. The second direction Y is perpendicular to the direction of the thickness of the display panel 101 and is perpendicular to the side end surface 15 of the base substrate 1. The third direction Z is perpendicular to the direction of the thickness of the display panel 101 and is parallel to the side end surface 15 of the base substrate 1.

In this embodiment of the present application, the base substrate 1 also includes a first surface 11 and a second surface 12 that are not parallel, and the first surface 11 and the second surface 12 may be directly connected or indirectly connected. The degree of inclination of the first surface 11 relative to the plane in which the display panel 101 is located is greater than the degree of inclination of the second surface 12 relative to the plane in which the display panel is 101 located. That is, the angle between the plane in which the first surface 11 is located and the plane in which the side end surface 15 is located is smaller than the angle between the plane in which the second surface 12 is located and the plane in which the side end surface 15 is located. It should be noted that in this embodiment of the present application, the angle between two planes refers to a smaller acute angle. When the two planes are parallel or overlap, the angle between the two planes is 0°. When the two planes are perpendicular to each other, the angle between the two planes is 90°. It should be noted that the first surface 11 and the second surface 12 are parallel to the third direction Z.

Considering that part of the circuits of the display panel 101 in this embodiment of the present application are located at the front side of the base substrate 1 and that part of the circuits are located at the back side of the base substrate 1, the first signal line 2 is configured to transmit a signal between the two parts of circuits. At least part of the first signal line 2 is in contact and connected with the first surface 11, and at least part of the first signal line 2 is in contact and connected with the second surface 12. Considering that the first surface 11 is further toward the side end surface 15 than the second surface 12, the part in which the first signal line 2 is in contact with the first surface 11 is prone to stress concentration. The equivalent roughness of the second surface 12 is less than the equivalent roughness of the first surface 11. In this manner, the connection between the first signal line 2 and the first surface 11 is made stronger to reduce the risk of splitting and detachment caused by stress concentration. It should be noted that in the embodiments of the present application, the equivalent roughness is not in a narrow sense. In addition to adjusting the equivalent roughness of the surface by grinding, the equivalent roughness of the surface may be adjusted by making additional protrusions or recesses on the surface.

It should be noted that in this embodiment of the present application, the display panel 101 also includes an array layer 3 and a light-emitting device layer 4. The array layer 3 is located at one side of the base substrate 1, and the front surface of the base substrate 1 faces the array layer 3. The light-emitting device layer 4 includes multiple light-emitting devices and is located on the side of the array layer 3 away from the base substrate 1. A light-emitting device may be an organic light-emitting diode (OLED) or a micro light-emitting diode (Micro-LED).

FIG. 4 is a side view of an edge of a base substrate of a display panel in a third direction according to an embodiment of the present application.

Further, with reference to FIG. 4, the first surface 11 is parallel to a direction of the thickness of the base substrate 1, and the second surface 12 is perpendicular to the direction of the thickness of the base substrate 1.

The first surface 11 is parallel to a direction of the thickness of the base substrate 1, that is, the first surface 11 may be the side end surface 15 of the base substrate 1. In this case, the angle between the plane in which the first surface 11 is located and the plane in which the side end surface 15 is located is 0°. The second surface 12 is perpendicular to the direction of the thickness of the base substrate 1, that is, the second surface 12 may be the front surface or the back surface. In this case, the angle between the plane in which the second surface 12 is located and the plane in which the side end surface 15 is located is 90°.

In this embodiment of the present application, the applicant also finds that as the edge of the surface of the substrate 1 continues to transition from being parallel to the plane in which the display panel 101 is located to the end surface, the contact stability of the side wires at the end of the display panel needs to be improved, and the roughness of the end needs to be increased. Moreover, in the extension path of the first signal line 2, the situations faced by the first signal line 2 are different as the end surface continues to be approached. For different positions of the first signal line 2, although those positions all belong to the first signal line 2, the closer to the plane parallel to the end surface of the display panel 101, the more the reliability of the first signal line 2 needs to be enhanced. For example, it is more necessary to avoid friction separation and relieve stress; the further away from the end surface is, the more necessary it is to control the roughness while preventing the risk of edge collapse. It should be noted that the end surface herein is understood as a surface perpendicular to the plane in which the display panel 101 is located, that is, the surface where adjacent display panels are adjacent to or in contact with each other when display panels are spliced.

Therefore, in the present application, different roughness may be configured in different regions at the end of the base substrate to satisfy the stability of side wires. Moreover, the edge collapse is avoided while a roughened surface is achieved.

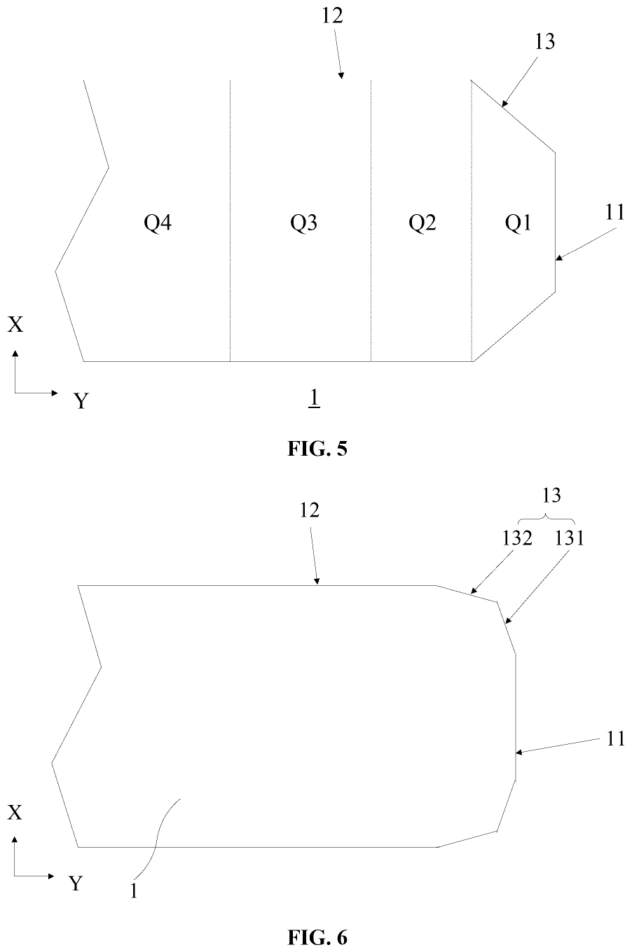

FIG. 5 is another side view of an edge of a base substrate of a display panel in a third direction according to an embodiment of the present application.

Further, with reference to FIG. 5, the base substrate 1 also includes a third surface 13 connected between the first surface 11 and the second surface 12, and the first surface 11 is parallel to the direction of the thickness of the base substrate. The degree of inclination of the first surface 11 relative to the plane in which the display panel 101 is located, the degree of inclination of the third surface 13 relative to the plane in which the display panel 101 is located, and the degree of inclination of the second surface 12 relative to the plane in which the display panel 101 is located decrease in sequence. The equivalent roughness of the second surface 12 is less than equivalent roughness of the third surface 13, and the equivalent roughness of the third surface 13 is less than the equivalent roughness of the first surface 11. The third surface 13 is connected between the first surface 11 and the second surface 12 so that the first surface 11, the third surface 13, and the second surface 12 are connected in sequence. The degree of inclination of the first surface 11 relative to the plane in which the display panel 101 is located, the degree of inclination of the third surface 13 relative to the plane in which the display panel 101 is located, and the degree of inclination of the second surface 12 relative to the plane in which the display panel 101 is located decrease in sequence. That is, compared with the side end surface 15, the second surface 12, the third surface 13, and the first surface 11 are sequentially closer to the side end surface 15. The angle between the plane in which the first surface 11 is located and the plane in which the side end surface 15 is located, the angle between the plane in which the third surface 13 is located and the plane in which the side end surface 15 is located, and the angle between the plane in which the second surface 12 is located and the plane in which the side end surface 15 is located increase in sequence. The first surface 11 is parallel to the direction of the thickness of the base substrate. The first surface 11 may be the side end surface 15. Considering that the closer to the side end surface 15 is, the more likely stress concentration is to occur on the first signal line 2. Therefore, the equivalent roughness of the second surface 12 is less than equivalent roughness of the third surface 13, and the equivalent roughness of the third surface 13 is less than the equivalent roughness of the first surface 11 so that the connection firmness between the second signal line and the first surface 11, the connection firmness between the first signal line 2 and the third surface 13, and the connection firmness between the first signal line 2 and the first surface 11 increase in sequence to reduce the risk of damage to the display panel 101 due to stress concentration. Further, with continued reference to FIG. 5, the first surface 11 is parallel to the direction of the thickness of the base substrate 1, the second surface 12 is perpendicular to the direction of the thickness of the base substrate 1, and the first surface 11 and the second surface 12 intersect the third surface 13.

The first surface 11 is parallel to the direction of the thickness of the base substrate 1, that is, the first surface 11 may be the side end surface 15 of the base substrate 1. In this case, the angle between the plane in which the first surface 11 is located and the plane in which the side end surface 15 is located is 0°. The second surface 12 is perpendicular to the direction of the thickness of the base substrate 1, that is, the second surface 12 may be the front surface or the back surface. In this case, the angle between the plane in which the second surface 12 is located and the plane in which the side end surface 15 is located is 90°. Both the first surface 11 and the second surface 12 intersect the third surface 13. The third surface 13 may be a chamfered surface between the first surface 11 and the second surface 12.

It should be noted that in this embodiment of the present application, the base substrate 1 in the second direction Y includes a chamfer region Q1, a glass processing tolerance reserved region Q2, a signal line overlap region Q3, and a protective film heat-affected region Q4 that are connected in sequence. The connection between the signal line overlap region Q3 and the protective film heat-affected region Q4 is a protective film cutting reference line. In this embodiment of the present application, the third surface 13 serves as a chamfered surface and is located in the chamfer region Q1.

FIG. 6 is another side view of an edge of a base substrate of a display panel in a third direction according to an embodiment of the present application.

Further, with reference to FIG. 6, the third surface 13 includes a first sub-surface 131 and a second sub-surface 132. The second surface 12, the second sub-surface 132, the first sub-surface 131, and the first surface 11 are connected in sequence, and the degree of inclination of the first sub-surface 131 relative to the plane in which the display panel 101 is located is greater than the degree of inclination of the second sub-surface 132 relative to the plane in which the display panel 101 is located. The equivalent roughness of the second surface 12 is less than the equivalent roughness of the second sub-surface 132, and the equivalent roughness of the first sub-surface 131 is less than the equivalent roughness of the first surface 11.

The second surface 12, the second sub-surface 132, the first sub-surface 131, and the first surface 11 are connected in sequence and are directed toward the side end surface 15 in sequence. In addition, the equivalent roughness of the second surface 12 is less than the equivalent roughness of the second sub-surface 132, and the equivalent roughness of the first sub-surface 131 is less than the equivalent roughness of the first surface 11. The first sub-surface 131 and the second sub-surface 132 are equivalent to consecutive chamfered surfaces between the first surface 11 and the second surface 12. Similarly, stress concentration is more likely to occur when the side end surface 15 is more directed, so the equivalent roughness of the second surface 12, the equivalent roughness of the second sub-surface 132, the equivalent roughness of the first sub-surface 131, and the equivalent roughness of the first surface 11 increase in sequence to reduce the risk of damage to the display panel 101 due to stress concentration.

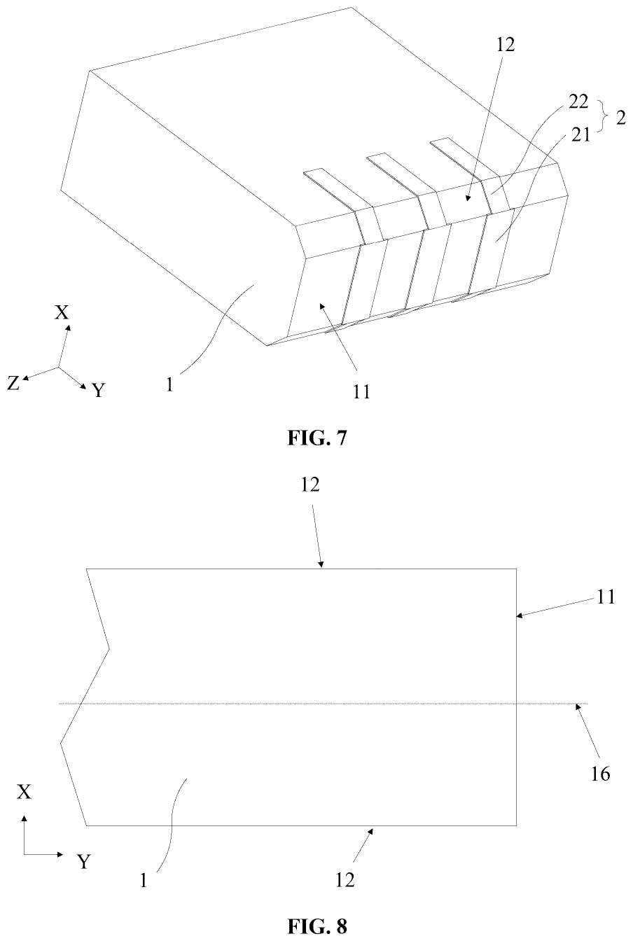

FIG. 7 is another side view of an edge of a base substrate of a display panel in a third direction according to an embodiment of the present application.

Further, with reference to FIG. 7, the first signal line 2 includes a first signal line segment 21 and a second signal line segment 22 that are electrically connected, the first signal line segment 21 is in contact and connected with the first surface 11, and the second signal line segment is in contact and connected with the second surface 12; in a first direction, the width of the first signal line segment 21 is greater than or equal to the width of the second signal line segment 22, the first direction is parallel to the first surface 11, and the first direction is parallel to the second surface 12.

For ease of description, in this embodiment of the present application, the first surface 11 is perpendicular to the second direction Y, that is, the first surface 11 is the side end surface 15 of base substrate 1, the second surface 12 is inclined to the first direction X and the second direction Y, that is, the second surface 12 is a chamfered surface between the side end surface 15 of the base substrate 1 and the front surface or the back surface of the base substrate 1.

The first signal line segment 21 is in contact and connected with the first surface 11, and the second signal line segment 22 is in contact and connected with the second surface 12. Both contact connections may be connected in a fixed manner. Optionally, the first signal line segment 21 is fixed to the first surface 11, and the second signal line segment 22 is fixed to the second surface 12. In the first direction, the width of the first signal line segment 21 is greater than or equal to the width of the second signal line segment 22. Therefore, the contact area between the first signal line segment 21 and the first surface 11 is greater than the contact area between the second signal line segment and the second surface, and thus the connection firmness between the first signal line segment 21 and the first surface 11 is stronger than the connection firmness between the second signal line segment 22 and the second surface 12. In this manner, the risk of damage to the display panel 101 due to stress concentration is reduced. On the one hand, the risk of the second surface 12 colliding with an external structure is less than that of the first surface 11. Therefore, the wiring width of the second signal line segment 22 can be reduced, the short circuit caused by the second signal line segment 22 being too dense is avoided, and the difficulty of making wires at the chamfer is reduced. In another aspect, since the equivalent roughness of the second surface 12 is relatively small, material deposition at the chamfer can be avoided, thereby assisting the formation of wires with controllable widths.

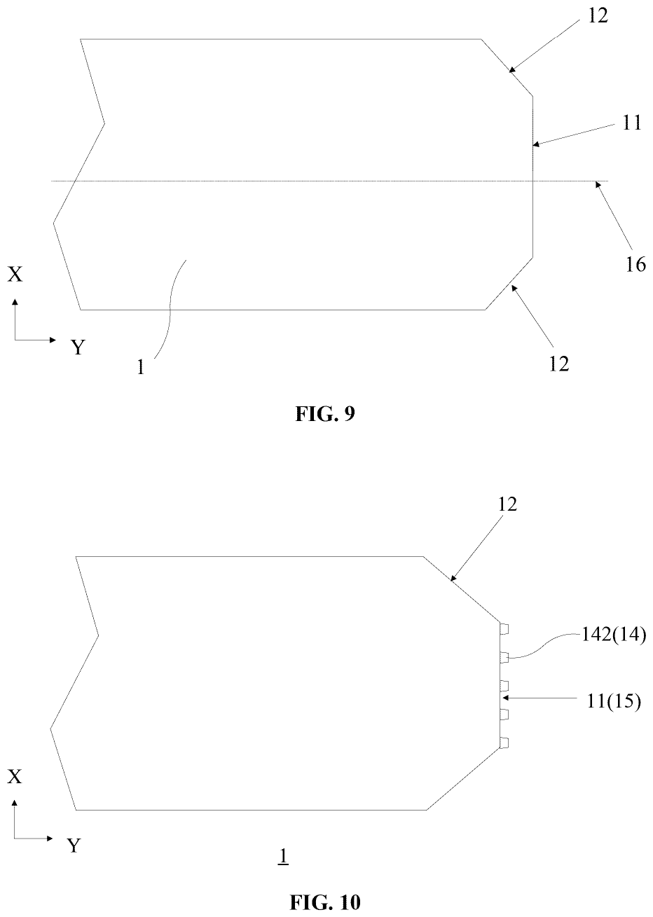

FIG. 8 is another side view of an edge of a base substrate of a display panel in a third direction according to an embodiment of the present application. FIG. 9 is another side view of an edge of a base substrate of a display panel in a third direction according to an embodiment of the present application.

Further, with reference to FIG. 8 and FIG. 9, multiple second surfaces 12 are provided, at least two second surfaces 12 are separately located on two sides of a first reference surface 16 and have the same orthographic projections on the first reference surface 16, and the first reference surface 16 is perpendicular to the direction of the thickness of the base substrate 1.

The two second surfaces 12 are separately located on two sides of the first reference surface 16 and are symmetrical with respect to the first reference surface 16. Illustratively, the two second surfaces 12 may be the front surface and the back surface of the base substrate 1. The side end surface 15 of the base substrate 1 is symmetrical with respect to the first reference surface 16, that is, the first reference surface 16 is perpendicular to the side end surface 15 and passes through the center line of the side end surface 15. The two second surfaces 12 may also be a chamfered surface between the front surface and the side end surface 15 of the base substrate 1 and a chamfered surface between the back surface and the side end surface 15 of the base substrate 1.

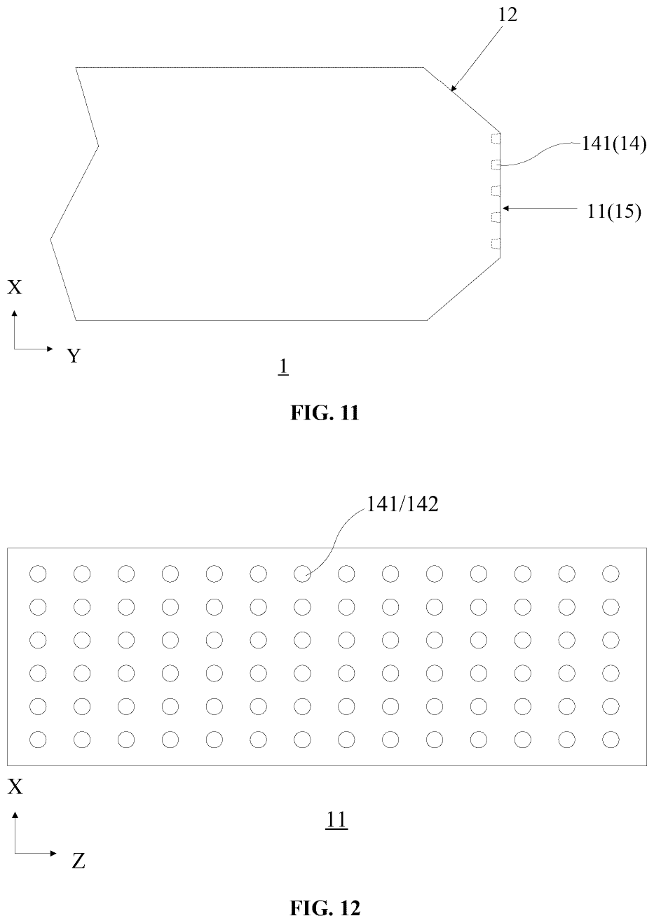

FIG. 10 is another side view of an edge of a base substrate of a display panel in a third direction according to an embodiment of the present application. FIG. 11 is another side view of an edge of a base substrate of a display panel in a third direction according to an embodiment of the present application.

Further, with reference to FIG. 10 and FIG. 11, the first surface 11 includes multiple micro-structure parts 14, and a micro-structure part 14 includes a first recess part 141 and/or a first protrusion part 142.

The equivalent roughness of the first surface 11 may be increased by the formation of the micro-structure part 14 on the first surface 11. The micro-structure part 14 includes a first recess part 141 and/or a first protrusion part 142. When the first recess part 141 is manufactured, part of the material may be directly removed from the first surface 11 to form the first recess part 141. When the first protrusion part 142 is manufactured, part of the material may be directly added to the first surface 11 to form the first protrusion part 142.

FIG. 12 is a side view of a first surface of the base substrate of the display panel in a second direction according to the embodiment of the present application in FIG. 11 or FIG. 10.

Further, with reference to FIG. 12, micro-structure parts 14 are evenly distributed on the first surface 11 so that the equivalent roughness of the first surface 11 can be uniformly increased as a whole. When the first signal line 2 is connected to the first surface 11, the positioning accuracy requirement for the relative position of the first signal line 2 and the first surface 11 may be appropriately relaxed, thereby reducing the manufacturing cost of the display panel 101 according to the embodiment of the present application.

Further, with continued reference to FIG. 12, in the plane in which the first surface 11 is located, the orthographic projection of the first recess part 141 is a combination of one or more of a circle, an ellipse, and a polygon.

When the micro-structure part 14 includes a first recess part 141, the first recess part 141 may be manufactured by drilling so that the orthographic projection of the first recess part 141 on the plane in which the first surface 11 is located is a combination of one or more of a circle, an ellipse, and a polygon.

Further, with continued reference to FIG. 12, in the plane in which the first surface 11 is located, the orthographic projection of the first protrusion part 142 is a combination of one or more of a circle, an ellipse, and a polygon.

When the micro-structure part 14 includes a first protrusion part 142, the first protrusion part 142 may be manufactured by adding a material to the first surface 11 so that the orthographic projection of the first protrusion part 142 on the plane in which the first surface 11 is located is a combination of one or more of a circle, an ellipse, and a polygon.

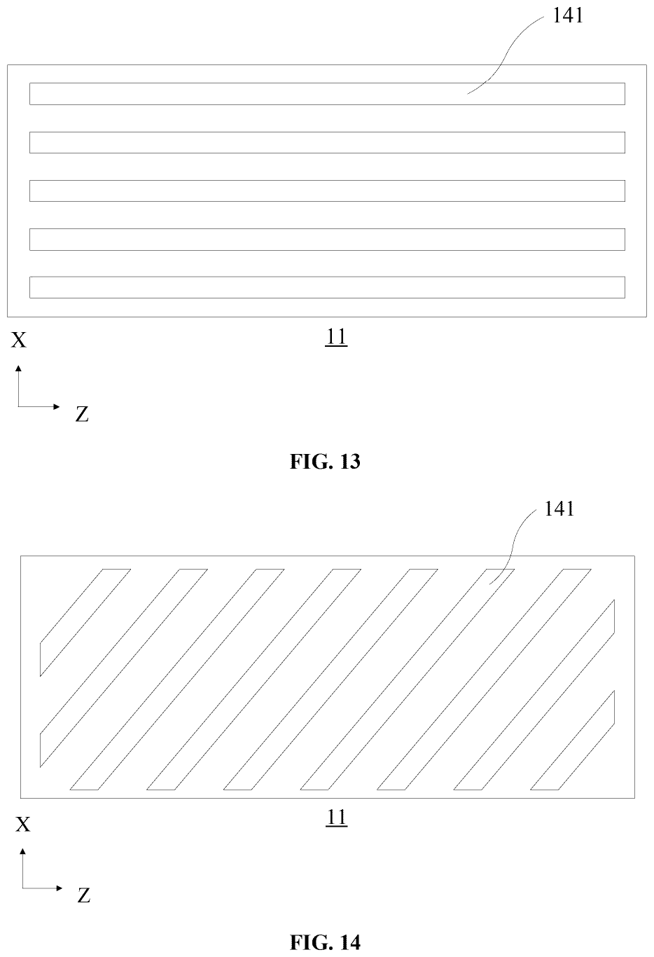

FIG. 13 is another side view of a first surface of the base substrate of the display panel in a second direction according to the embodiment of the present application in FIG. 11. FIG. 14 is another side view of a first surface of the base substrate of the display panel in a second direction according to the embodiment of the present application in FIG. 11.

Further, with reference to FIG. 13 and FIG. 14, the first recess part 141 is in a strip shape, multiple first recess parts 141 are disposed in parallel, and the extension direction of the first recess part 141 intersects the direction of the thickness of the base substrate 1.

When the micro-structure part 14 includes a first recess part 141, the first recess part 141 may be fabricated by making a groove so that the orthographic projection of the first recess part 141 on the plane in which the first surface 11 is located is a stripe. That is, the orthographic projection of the first recess part 141 includes two opposite sides that are parallel to each other. The extension direction of the first recess part 141 is not parallel to the first direction X (the direction of the thickness of the base substrate 1).

Optionally, as shown in FIG. 14, when the micro-structure part 14 includes a first recess part 141, the first recess part 141 may be fabricated by making a groove so that the orthographic projection of the first recess part 141 on the plane in which the first surface 11 is located is a stripe. That is, the orthographic projection of the first recess part 141 includes two opposite sides that are parallel to each other. The extension direction of the first recess part 141 is not parallel to the first direction X (the direction of the thickness of the base substrate 1) so that the first signal line 2 can always cross multiple first recess parts 141 in the first direction X (that is, a direction perpendicular to the plane in which the display panel is located) and may not vertically overlap the first recess part 141. That is, the extension direction of the first recess part 141 also overlaps the Z direction. Such a design can enable the first recess part 141 to always cross multiple first signal lines 2 in the first direction X. Moreover, such a design enables the first signal line 2 to be securely connected to the first surface 11 and avoids excessive stress caused by increased overlap between the first signal line 2 and the first recess part 141.

As shown in FIG. 13, multiple strip-shaped micro-structure parts 14 (herein, the first recess part 141 is used as an example) extend in the third direction Z.

In this design, the first signal line 2 can always cross multiple first recess parts 141 in its extension direction (that is, a direction perpendicular to the plane in which the display panel is located, namely, the X direction). In addition, the first recess part 141 can always cross multiple first signal lines 2 in its extension direction. In this manner, the contact surface corresponding to each wire can be as close as possible, thereby improving the uniform stability of each wire. In addition, under the premise that the width and the distance of the first recess part 141 are constant values, when the extension direction of the first recess part 141 is parallel to the third direction Z, the first signal line 2 may overlap more first recess parts 141, although the overlapping area between the first signal line 2 and a single first recess part 141 is smaller. Thus, the connection between the first signal line 2 and the first surface 11 can be further improved.

Further, optionally, the second surface 12 also has a micro-structure part 14. Optionally, the micro-structure part 14 on the second surface 12 may be fabricated by making a groove or protrusion. For a specific structure, reference may be made to the preceding design of the micro-structure part 14 on the first surface 11. Differently, the extension direction of the micro-structure part 14 on the second surface 12 is different from the extension direction of the micro-structure part 14 on the first surface 11.

In some optional embodiments of the present application, when the micro-structure part 14 includes a first protrusion part 142, the first protrusion part 142 may be fabricated by groove opening so that the orthographic projection of the first protrusion part 142 on the plane in which the first surface 11 is located is a stripe. That is, the orthographic projection of the first protrusion part 141 includes two opposite sides that are parallel to each other. The extension direction of the first protrusion 142 is not parallel to the first direction X so that the first signal line 2 can always cross multiple first protrusion parts 142 in the first direction X (that is, a direction perpendicular to the plane in which the display panel is located)). Thus, the first signal line 2 can be securely connected to the first surface 11. For the design of the second surface 12, reference may be made to the preceding description of the first recess part 142. Details are not repeated herein.

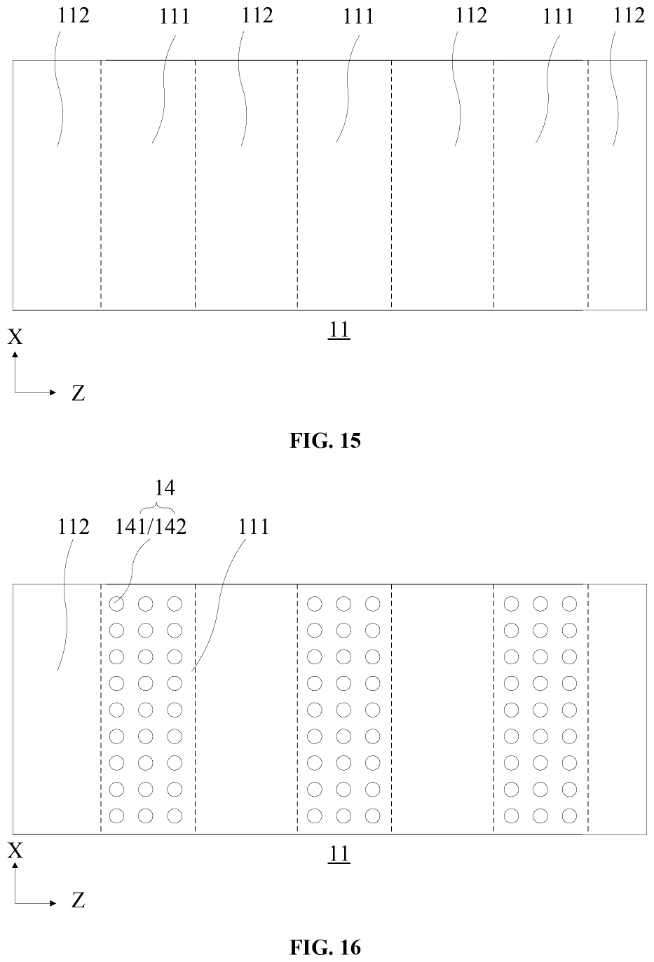

FIG. 15 is another side view of a first surface of the base substrate of the display panel in a second direction according to the embodiment of the present application in FIG. 8. In FIG. 15, a wiring region 111 and a non-wiring region 112 are separated by dotted lines.

Further, with reference to FIG. 15, the first surface 11 includes a wiring region 111 and a non-wiring region 112. In the plane in which the first surface 11 is located, the orthographic projection of the first signal line 2 at least partially overlaps the orthographic projection of the wiring region 111, and the equivalent roughness of the first surface 11 is less than the equivalent roughness of the non-wiring region 112, and the equivalent roughness of the non-wiring region 112 is less than equivalent roughness of the wiring region 111.

The equivalent roughness of the first surface 11 may not be completely equal everywhere. The first surface 11 includes a wiring region 111 and a non-wiring region 112. The first signal line 2 is fixedly connected to the first surface 11 in the wiring region 111. Another region that is not covered by the first signal line 2 is the non-wiring region 112. When the first surface 11 is processed, only the wiring region 111 may be processed. In this manner, the equivalent roughness of the wiring region 111 is increased, the workload of processing the first surface 11 is reduced, and the manufacturing efficiency of the display panel 101 according to this embodiment of the present application is improved. Considering that multiple first signal lines 2 may be provided and each first signal line 2 crosses the first surface 11 in the first direction X, the wiring region 111 and non-wiring region 112 are alternately arranged in the third direction Z in the first surface 11.

Further, with continued reference to FIG. 15, the first surface 11 is parallel to the direction of the thickness of the base substrate 1, the equivalent roughness of the second surface 12 is less than the equivalent roughness of the wiring region 111, and the difference between the equivalent roughness of the second surface 12 and the equivalent roughness of the non-wiring region 112 is less than a preset difference.

In this embodiment of the present application, the second surface 12 may be a chamfered surface between the side end surface 15 of the base substrate 1 and the front surface or the back surface of the base substrate 1, the first surface 11 may be a side end surface 15 of the base substrate 1, and the equivalent roughness of the second surface 12 is less than the equivalent roughness of the wiring region 111, so as to reduce the risk of damage to the display panel 101 due to stress concentration. The difference between the equivalent roughness of the second surface 12 and the equivalent roughness of the non-wiring region 112 is less than a preset difference. When the second surface 12 is processed to increase the equivalent roughness, the first surface 11 may be processed together, and then the wiring region 111 of the first surface 11 is further processed to further increase the equivalent roughness. Therefore, the equivalent roughness of the second surface 12 is basically equal to the equivalent roughness of the non-wiring region 112.

FIG. 16 is another side view of a first surface of the base substrate of the display panel in a second direction according to the embodiment of the present application in FIG. 8.

Further, with reference to FIG. 16, the first surface 11 includes multiple micro-structure parts 14, a micro-structure part 14 includes a first recess part 141 and/or a first protrusion part 142, and the micro-structure part 14 is located in the wiring region 111.

When the first surface 11 includes a wiring region 111 and a non-wiring region 112, the micro-structure part 14 may be disposed in the wiring region 111 to increase the equivalent roughness of the wiring region 111. That is, a first recess part 141 and/or a first protrusion part 142 are manufactured in the wiring region 111.

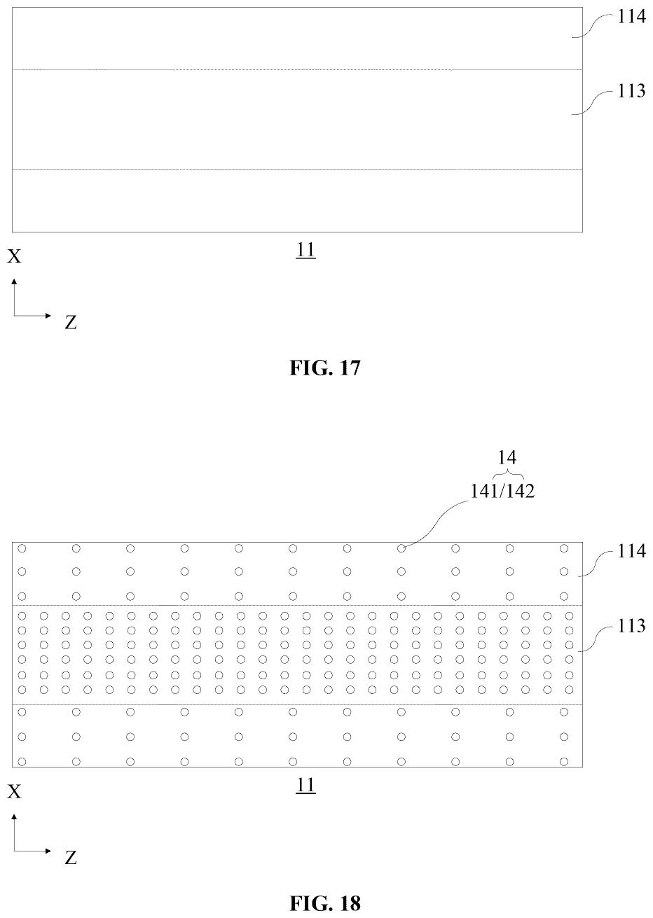

FIG. 17 is another side view of a first surface of the base substrate of the display panel in a second direction according to the embodiment of the present application in FIG. 8.

Further, with reference to FIG. 17, the first surface includes a first sub-region 113 and a second sub-region 114. In the direction of the thickness of the base substrate 1, the distance from the first sub-region 113 to the second surface 12 is greater than the distance from the second sub-region 114 to the second surface 12, and the equivalent roughness of the first sub-region 113 is greater than the equivalent roughness of the second sub-region 114.

In the first direction X, the first sub-region 113 of the first surface 11 is further away from the second surface 12 than the second sub-region 114. When the first signal line 2 is fixedly connected to the first surface 11, the first sub-region 113 in the first surface 11 is more likely to be split or detached than the second sub-region 114. Since the equivalent roughness of the first sub-region 113 is greater than the equivalent roughness of the second sub-region 114, the connection firmness between the first signal line 2 and the first surface 11 in the first sub-region 113 is greater than the connection firmness between the first signal line 2 and the first surface 11 in the second sub-region 114. Therefore, the risk of splitting or detachment of the first signal line 2 from the first surface 11 can be reduced in the first sub-region 113.

FIG. 18 is another side view of a first surface of the base substrate of the display panel in a second direction according to the embodiment of the present application in FIG. 8.

Further, with reference to FIG. 18, the first surface 11 includes multiple micro-structure parts 14, and a micro-structure part 14 includes a first recess part 141 and/or a first protrusion part 142. At least part of the multiple micro-structure parts 14 are located in the first sub-region 113, and at least part of the multiple micro-structure parts 14 are located in the second sub-region 114. In the first sub-region 113, the ratio of the area of the multiple micro-structure parts 14 to the area of the first sub-region 113 is S1, and in the second sub-region 114, the ratio of the area of the multiple micro-structure parts 14 to the area of the second sub-region 114 is S2, where S1>S2.

When the equivalent roughness of the first surface 11 is increased by the configuration of micro-structure parts 14, since the equivalent roughness of the first sub-region 113 is greater than the equivalent roughness of the second sub-region 114, more micro-structure parts 14 may be disposed in the first sub-region 113. That is, the area ratio S1 of the area of multiple micro-structure parts 14 to the area of the first sub-region 113 is greater than the area ratio S2 of the area of the multiple micro-structure parts 14 to the area of the second sub-region 114, and it may also be considered that the density of the micro-structure parts 14 in 113 is greater than the density of the micro-structure parts 14 in the second sub-region 114.

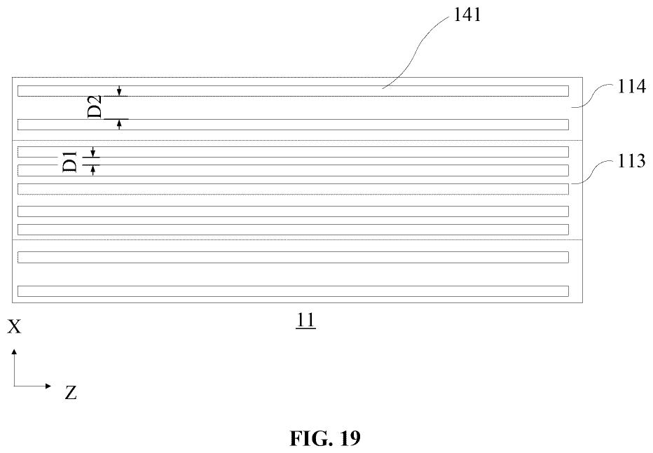

FIG. 19 is another side view of a first surface of the base substrate of the display panel in a second direction according to the embodiment of the present application in FIG. 8.

Further, with reference to FIG. 19, the first recess part 141 is in a strip shape, multiple first recess parts 141 are disposed in parallel, and the extension direction of the first recess part 141 intersects the direction of the thickness of the base substrate 1. In the first sub-region 113, the interval between the multiple first recess parts 141 is D1, and in the second sub-region 114, the interval between the multiple first recess parts 141 is D2, where D1<D2.

When the micro-structure part 14 of the first surface 11 adopts strip-shaped first recess parts 141, the equivalent roughness may be increased by the reduction of the interval of the first recess parts 141. That is, the interval D1 of the multiple first recess parts 141 in the first sub-region 113 is less than the distance D2 of the multiple first recess parts 141 in the second sub-region 114 so that the equivalent roughness of the first sub-region 113 is greater than the equivalent roughness of the second sub-region 114.

It should be noted that in this embodiment of the present application, the first surface 11 may be perpendicular to the second direction Y, that is, the first surface 11 may be a side end surface 15 of the base substrate 1. The second surface 12 is used to assist the wiring of the first signal line 2 so that the transition of the first signal line 2 from the front surface or the back surface of the base substrate 1 to the side end surface 15 is smoother. Therefore, the second surface 12 is closer to being parallel to the plane in which the display panel 101 is located. In the process of the first signal line 2 gradually transitioning from the front or back surface of the base substrate 1 to the side end surface 15, the more likely the first signal line 2 is about being parallel to the side end surface 15, the greater the degree of bending of the first signal line 2 is, and the easier it is for edge chipping or breakage to occur. In the first surface 11 and the second surface 12 of this embodiment of the present application, the relative roughness of the first surface 11 that is closer to being parallel to the side end surface 15 is increased so that the connection firmness between the first signal line 2 and the first surface 11 is strengthened. Therefore, this embodiment of the present application is more suitable for, as for the relative roughness, the part of the base substrate 1 that is gradually close to being parallel to the side end surface 15.

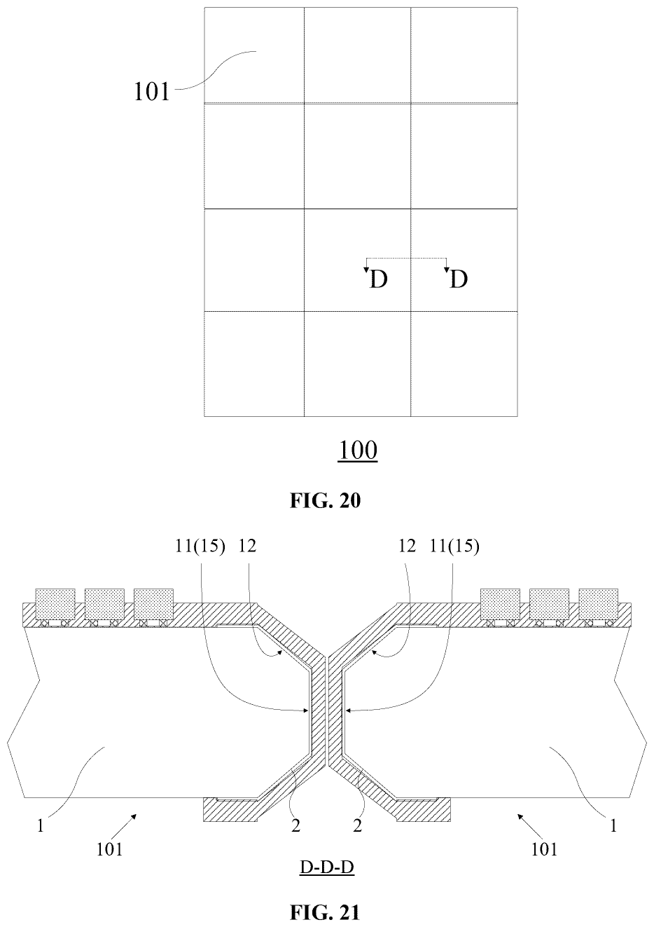

FIG. 20 is a diagram illustrating the structure of a display device according to an embodiment of the present application. FIG. 21 is a sectional view of the display device taken along D-D according to the embodiment of the present application in FIG. 20.

With reference to FIG. 20 and FIG. 21, this embodiment of the present application also provides a display device 100. The display device 100 includes multiple display panels 101 described in the embodiments of the present application. Multiple display panels 101 are disposed in parallel. The first surfaces 11 of two adjacent display panels 101 are in contact and connected with each other. In this case, the first surface 11 is the side end surface 15 of the base substrate 1. It should be noted that in this embodiment of the present application, the first surfaces 11 of two adjacent display panels 101 are close to each other, and an inevitable gap may exist.

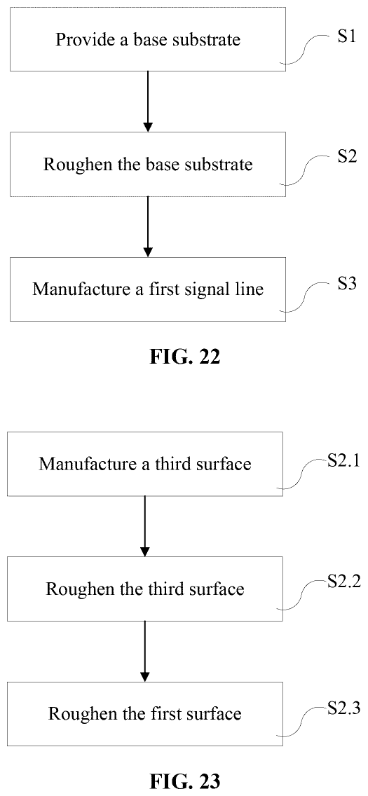

FIG. 22 is a flowchart of a method for manufacturing a display panel according to an embodiment of the present application.

With reference to FIG. 22, this embodiment of the present application also provides a method for manufacturing a display panel 101, which may be used to manufacture the display panel 101 of the preceding embodiments of the present application.

Specifically, the method for manufacturing the display panel 101 in this embodiment of the present application includes the steps below.

In S1, a base substrate 1 is provided.

The base substrate 1 may be acquired by manufacturing; or the finished product of the base substrate 1 may be acquired directly. The base substrate 1 includes a first surface 11 and a second surface 12. The degree of inclination of the first surface 11 relative to the plane in which the display panel 101 is located is less than the degree of inclination of the second surface 12 relative to the plane in which the display panel is 101 located. That is, the angle between the plane in which the first surface 11 is located and the plane in which the side end surface 15 is located is smaller than the angle between the plane in which the second surface 12 is located and the plane in which the side end surface 15 is located. The base substrate 1 includes opposite front and back surfaces. The front surface faces a light-emitting device of the display panel 101. In the second direction Y, the base substrate 1 also includes a side end surface 15. Illustratively, the first surface 11 may be the side end surface 15 of the base substrate 1, and the second surface 12 may be the front or back surface of the base substrate 1.

In S2, the base substrate 1 is roughened.

The base substrate 1 is roughened by grinding so that the equivalent roughness of the second surface 12 is less than the equivalent roughness of the first surface 11. It should be noted that in the embodiments of the present application, the equivalent roughness is not in a narrow sense. In addition to adjusting the equivalent roughness of the surface by grinding, the equivalent roughness of the surface may be adjusted by making additional protrusions or recesses on the surface.

In S3, a first signal line 2 is manufactured.

Considering that part of the circuits of the display panel 101 in this embodiment of the present application are located at the front side of the base substrate 1 and that part of the circuits are located at the back side of the base substrate 1, the first signal line 2 is configured to transmit a signal between the two parts of circuits. Part of the first signal line 2 is located on the second surface 12 and is in contact and fixedly connected with the second surface 12. Part of the first signal line 2 is located on the first surface 11 and is in contact and fixedly connected with the first surface 11.

Since the equivalent roughness of the second surface 12 is less than the equivalent roughness of the first surface 11, the connection between the first signal line 2 and the first surface 11 is stronger to reduce the risk of splitting and detachment caused by stress concentration.

It should be noted that this embodiment of the present application is more suitable for, as for the relative roughness configuration, the part of the base substrate 1 that is gradually close to being parallel to the side end surface 15. The equivalent roughness of the first surface 11 is greater than the equivalent roughness of the second surface 12 in different manners. For surfaces of different regions of the end of the base substrate 1 in the second direction Y, different roughening methods are used to improve the stability of the side wires and reduce risks such as edge chipping.

FIG. 23 is a flowchart of S2 of the method for manufacturing a display panel according to an embodiment of the present application.

Further, with reference to FIG. 23, S2 includes the steps below.

In S2.1, a third surface 13 is manufactured.

A third surface 13 is manufactured at one end of the second surface 12 adjacent to the first surface 11. The degree of inclination of the first surface 11 relative to the plane in which the display panel 101 is located, the degree of inclination of the third surface 13 relative to the plane in which the display panel 101 is located, and the degree of inclination of the second surface 12 relative to the plane in which the display panel 101 is located increase in sequence. The third surface 13 may be regarded as a chamfered surface between the first surface 11 and the second surface 12.

In S2.2, the third surface 13 is roughened.

The third surface 13 is roughened with a grinding wheel such that the equivalent roughness of the third surface 13 is greater than the equivalent roughness of the second surface 12, and the connection firmness between the first signal line 2 and the third surface 13 is greater than the connection firmness between the first signal line 2 and the second surface 12.

In S2.3, the first surface 11 is roughened.

The first surface 11 is roughened with a grinding rod such that the equivalent roughness of the third surface 13 is less than the equivalent roughness of the first surface 11, and the connection firmness between the first signal line 2 and the first surface 11 is greater than the connection firmness between the first signal line 2 and the third surface 13.

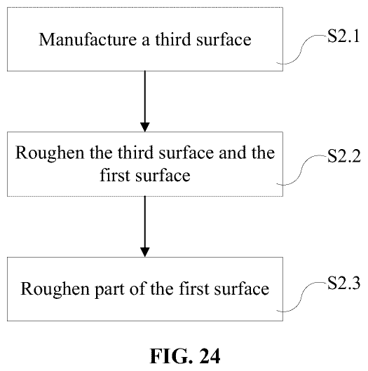

FIG. 24 is a flowchart of S2 of the method for manufacturing a display panel according to an embodiment of the present application.

Further, with reference to FIG. 24, S2 includes the steps below.

In S2.1, a third surface 13 is manufactured.

A third surface 13 is manufactured at one end of the second surface 12 adjacent to the first surface 11. The degree of inclination of the first surface 11 relative to the plane in which the display panel 101 is located, the degree of inclination of the third surface 13 relative to the plane in which the display panel 101 is located, and the degree of inclination of the second surface 12 relative to the plane in which the display panel 101 is located increase in sequence. The third surface 13 may be regarded as a chamfered surface between the first surface 11 and the second surface 12.

In S2.2, the third surface 13 and the first surface 11 are roughened.

The third surface 13 and the first surface 11 are roughened with a grinding wheel such that the equivalent roughness of the third surface 13 and the first surface 11 is greater than the equivalent roughness of the second surface 12, and the connection firmness between the first signal line 2 and the third surface 13 is greater than the connection firmness between the first signal line 2 and the second surface 12.

In S2.3, part of the first surface 11 is roughened.

Part of the first surface 11 is roughened with a grinding rod such that the first surface 11 includes a wiring region 111 and a non-wiring region 112, and the equivalent roughness of the wiring region 111 is greater than the equivalent roughness of the non-wiring region 112. The first signal line 2 is in contact and fixedly connected with the first surface 11 in the wiring region 111. The connection firmness between the first signal line 2 and the wiring region 111 is greater than the connection firmness between the first signal line 2 and the third surface 13.

Further, after S2 and before S3, multiple micro-structure parts 14 are manufactured on the first surface 11, and a micro-structure part 14 includes a first recess part 141 and/or a first protrusion part 142. When the first recess part 141 is manufactured, part of the material may be directly removed from the first surface 11 to form the first recess part 141. When the first protrusion part 142 is manufactured, part of the material may be directly added to the first surface 11 to form the first protrusion part 142.

To sum up, in the display panel, the display device, and the method for manufacturing a display panel provided by the embodiments of the present application, the substrate includes a first surface and a second surface that are not parallel, the first surface is more inclined relative to the plane in which the display panel is located, and the first surface is closer to the side end surface of the base substrate. The first surface and the second surface of the first signal line are in contact and connected simultaneously for transmitting signals. The equivalent roughness of the second surface is less than the equivalent roughness of the first surface, so the firmness of the connection between the first signal line and the first surface is greater than the firmness of the connection between the first signal line and the second surface. Thus, the risk of damage to the connection between the first surface and the first signal line caused by stress concentration can be effectively reduced, and the service life of the display panel described in embodiments of the present application can be extended.

In summary, the above are only specific embodiments of the present application and are not intended to limit the present application. It is easy for those skilled in the art to conceive equivalent modifications or substitutions within the technical scope of the present application. These modifications or substitutions are within the scope of the present application. Therefore, the protection scope of the present application is subject to the scope of the claims.

What is claimed is:

1. A display panel, comprising:
a base substrate comprising a first surface and a second surface, wherein a degree of inclination of the first surface relative to a plane in which the display panel is located is greater than a degree of inclination of the second surface relative to the plane in which the display panel is located; and
a first signal line, wherein at least part of the first signal line is in contact with the first surface, and at least part of the first signal line is in contact and connected with the second surface;
wherein equivalent roughness of the second surface is less than equivalent roughness of the first surface.

2. The display panel of claim 1, wherein the first surface is parallel to a thickness direction of the base substrate, and the second surface is perpendicular to the thickness direction of the base substrate.

3. The display panel of claim 1, wherein the base substrate further comprises a third surface, wherein third surface is connected between the first surface and the second surface, and the first surface is parallel to a thickness direction of the base substrate;
the degree of inclination of the first surface relative to the plane in which the display panel is located, a degree of inclination of the third surface relative to the plane in which the display panel is located, and the degree of inclination of the second surface relative to the plane in which the display panel is located decrease in sequence; and
the equivalent roughness of the second surface is less than equivalent roughness of the third surface, and the equivalent roughness of the third surface is less than the equivalent roughness of the first surface.

4. The display panel of claim 3, wherein the first surface is parallel to the thickness direction of the base substrate, the second surface is perpendicular to the thickness direction of the base substrate, and both the first surface and the second surface intersect the third surface.

5. The display panel of claim 3, wherein the third surface comprises a first sub-surface and a second sub-surface;
wherein the second surface, the second sub-surface, the first sub-surface, and the first surface are connected in sequence, and a degree of inclination of the first sub-surface relative to the plane in which the display panel is located is greater than a degree of inclination of the second sub-surface relative to the plane in which the display panel is located; and
the equivalent roughness of the second surface is less than equivalent roughness of the second sub-surface, and equivalent roughness of the first sub-surface is less than the equivalent roughness of the first surface.

6. The display panel of claim 1, wherein the first signal line comprises a first signal line segment and a second signal line segment;
wherein the first signal line segment and the second signal line segment are electrically connected to each other, the first signal line segment is in contact and connected with the first surface, and the second signal line segment is in contact and connected with the second surface; and
in a first direction, a width of the first signal line segment is greater than or equal to a width of the second signal line segment, the first direction is parallel to the first surface, and the first direction is parallel to the second surface.

7. The display panel of claim 1, wherein a plurality of second surfaces are provided, at least two second surfaces of the plurality of second surfaces are separately located on two sides of a first reference surface, and the first reference surface is perpendicular to a thickness direction of the base substrate.

8. The display panel of claim 1, wherein the first surface comprises a plurality of micro-structure parts, and a micro-structure part of the plurality of micro-structure parts comprises a first recess part and/or a first protrusion part.

9. The display panel of claim 8, wherein the plurality of micro-structure parts are evenly distributed on the first surface.

10. The display panel of claim 8, wherein in a plane in which the first surface is located, an orthographic projection of the first recess part is a combination of one or more of a circle, an ellipse, and a polygon.

11. The display panel of claim 8, wherein the first recess part is in a strip shape, a plurality of first recess parts are disposed in parallel, and an extension direction of the first recess part intersects a thickness direction of the base substrate.

12. The display panel of claim 8, wherein in a plane in which the first surface is located, an orthographic projection of the first protrusion part is a combination of one or more of a circle, an ellipse, and a polygon.

13. The display panel of claim 1, wherein the first surface comprises a wiring region and a non-wiring region;
in a plane in which the first surface is located, an orthographic projection of the first signal line at least partially overlaps an orthographic projection of the wiring region; and
the equivalent roughness of the first surface is less than equivalent roughness of the non-wiring region, and the equivalent roughness of the non-wiring region is less than equivalent roughness of the wiring region.

14. The display panel of claim 13, wherein the first surface is parallel to a thickness direction of the base substrate; the equivalent roughness of the second surface is less than the equivalent roughness of the wiring region; and a difference between the equivalent roughness of the second surface and the equivalent roughness of the non-wiring region is less than a preset difference.

15. The display panel of claim 13, wherein the first surface comprises a plurality of micro-structure parts, a micro-structure part of the plurality of micro-structure parts comprises a first recess part and/or a first protrusion part, and the micro-structure part is located in the wiring region.

16. The display panel of claim 1, wherein the first surface comprises a first sub-region and a second sub-region;
in a thickness direction of the base substrate, a distance from the first sub-region to the second surface is greater than a distance from the second sub-region to the second surface; and
equivalent roughness of the first sub-region is greater than equivalent roughness of the second sub-region.

17. The display panel of claim 16, wherein the first surface comprises a plurality of micro-structure parts, and a micro-structure part of the plurality of micro-structure parts comprises a first recess part and/or a first protrusion part;
at least part of the plurality of micro-structure parts are located in the first sub-region, and at least part of the plurality of micro-structure parts are located in the second sub-region; and
in the first sub-region, a ratio of an area of the plurality of micro-structure parts to an area of the first sub-region is S1; and in the second sub-region, a ratio of an area of the plurality of micro-structure parts to an area of the second sub-region is S2; wherein S1>S2.

18. The display panel of claim 17, wherein the first recess part is in a strip shape, a plurality of first recess parts are disposed in parallel, and an extension direction of the first recess part intersects the thickness direction of the base substrate; in the first sub-region, a distance between the plurality of first recess parts is D1; and in the second sub-region, a distance between the plurality of first recess parts is D2; wherein D1<D2.

19. A display device, comprising display panels, each of the display panels comprises:
a base substrate comprising a first surface and a second surface, wherein a degree of inclination of the first surface relative to a plane in which the display panel is located is greater than a degree of inclination of the second surface relative to the plane in which the display panel is located; and
a first signal line, wherein at least part of the first signal line is in contact with the first surface, and at least part of the first signal line is in contact and connected with the second surface;
wherein equivalent roughness of the second surface is less than equivalent roughness of the first surface;
wherein the display panels are disposed in parallel, and first surfaces of two adjacent display panels are in contact with each other.

20. A method for manufacturing a display panel, comprising:
providing a base substrate, wherein the base substrate comprises a first surface and a second surface, and degree of inclination of the first surface relative to a plane in which the display panel is located is greater than a degree of inclination of the second surface relative to the plane in which the display panel is located; roughening the base substrate such that equivalent roughness of the second surface is less than equivalent roughness of the first surface; and
manufacturing a first signal line to enable part of the first signal line to be disposed in the second surface, and part of the first signal line is disposed in the first surface.

21. The method for manufacturing the display panel of claim 20, wherein roughening the base substrate comprises:
roughening the first surface with a grinding rod.

22. The method for manufacturing the display panel of claim 20, wherein roughening the base substrate comprises:
manufacturing a third surface at one end of the second surface closest to the first surface; wherein the degree of inclination of the first surface relative to the plane in which the display panel is located, a degree of inclination of the third surface relative to the plane in which the display panel is located, and the degree of inclination of the second surface relative to the plane in which the display panel is located decrease in sequence;
roughening the third surface with a grinding wheel such that equivalent roughness of the third surface is greater than the equivalent roughness of the second surface; and
roughening the first surface with a grinding rod such that the equivalent roughness of the third surface is less than the equivalent roughness of the first surface.

23. The method for manufacturing the display panel of claim 20, wherein roughening the base substrate comprises:
manufacturing a third surface at one end of the second surface closest to the first surface;
roughening the third surface and the first surface with a grinding wheel, wherein equivalent roughness of the third surface is greater than the equivalent roughness of the second surface; and
roughening part of the first surface with a grinding rod, wherein the first surface comprises a wiring region and a non-wiring region, and equivalent roughness of the wiring region is greater than equivalent roughness of the non-wiring region.

24. The method for manufacturing the display panel of claim 20, wherein after roughening the base substrate, the method further comprises:
manufacturing a plurality of micro-structure parts on the first surface, wherein a micro-structure part of the plurality of micro-structure parts comprises a first recess part and/or a first protrusion part.
